(19) United States
(12) Patent Application Publication
(10) Pub. No.: US 2012/0153479 A1
(43) Pub. Date: Jun. 21, 2012

(54) Performance Enhancement in Metallization Systems of Microstructure Devices by Incorporating an Intermediate Barrier Layer

(75) Inventors: Oliver Aubel, Dresden (DE); Christian Hennesthal, Niederau (DE); Frank Feustel, Dresden (DE); Thomas Werner, Dresden (DE)

(73) Assignee: GLOBALFOUNDRIES INC., Grand Cayman (KY)

(21) Appl. No.: 13/190,214

(22) Filed: Jul. 25, 2011

(30) Foreign Application Priority Data
Dec. 16, 2010 (DE) 10 2010 063 299.6

(51) Int. Cl. H01L 23/522; H01L 21/768

(52) U.S. Cl. 257/751; 438/643; 257/E21.584; 257/E23.145

(57) ABSTRACT

In metallization systems of complex semiconductor devices, an intermediate interface layer may be incorporated into the interconnect structures in order to provide superior electromigration performance. To this end, the deposition of the actual fill material may be interrupted at an appropriate stage and the interface layer may be formed, for instance, by deposition, surface treatment and the like, followed by the further deposition of the actual fill metal. In this manner, the grain size issue, in particular at lower portions of the scaled inter-connect features, may be addressed.

### BACKGROUND OF THE INVENTION

1. Field of the Invention

Generally, the present disclosure relates to microstructures, such as advanced integrated circuits, and, more particularly, to metallization systems with reduced dimensions and inferior grain size distribution in metal lines in metallization layers of integrated circuits.

2. Description of the Related Art

In the field of modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect structures electrically connecting the individual circuit elements is also decreased. Consequently, the dimensions of these inter-connect structures have to be reduced to compensate for a reduced amount of available floor space and for an increased number of circuit elements provided per unit die area. The reduced cross-sectional area of the interconnect structures, possibly in combination with an increase of the static power consumption of extremely scaled transistor elements, may require a plurality of stacked metallization layers to meet the requirements in view of a tolerable current density in the metal lines.

Advanced integrated circuits, including transistor elements having a critical dimension of approximately 40 nm and less, may, however, require significantly increased current densities in the individual metal lines despite the provision of a relatively large number of metallization layers owing to the high number of circuit elements per unit area. Operating the metal lines at elevated current densities, however, may entail a plurality of problems related to stress-induced line degradation, which may finally lead to a premature failure of the integrated circuit. One prominent phenomenon in this respect is the current-induced material diffusion in metal lines, also referred to as electromigration, which may lead to the formation of voids within and hillocks next to the metal line, thereby resulting in reduced performance and reliability or complete failure of the device. Electromigration is thus a phenomenon that typically occurs in metal lines when a significant momentum transfer from electrons to the core atoms or ions takes place. Due to this momentum transfer, the atoms or ions are displaced and thus move in the direction of the electron flow, thereby increasingly depleting upstream areas of less pronounced electromigration resistance, while accumulating metal material in specific downstream areas. This material depletion may increasingly reduce the cross-sectional area of the upstream area, thereby forming voids, and may finally result in a total failure of the metal line. The directed diffusion of metal atoms and ions may be “promoted” by the presence of pronounced diffusion paths, such as grain boundaries of metal grains, interfaces between the metal and a barrier material, and the like.

For instance, aluminum lines embedded into silicon dioxide and/or silicon nitride are frequently used as metal for metallization layers, wherein, as explained above, advanced integrated circuits having critical dimensions of 0.04 μm or less, may require significantly reduced cross-sectional areas of the metal lines and, thus, increased current densities, which may render aluminum less attractive for the formation of metallization layers due to significant electromigration effects.

Consequently, aluminum is increasingly being replaced by copper that exhibits a significantly lower electric resistivity and exhibits an enhanced resistance in view of electromigration effects at higher current densities as compared to aluminum. The introduction of copper into the fabrication of microstructures and integrated circuits creates a plurality of severe problems due to copper's characteristic to readily diffuse in silicon dioxide and a plurality of low-k dielectric materials. To provide the necessary adhesion and to avoid the undesired diffusion of copper atoms into sensitive device regions, it is, therefore, usually necessary to provide a barrier layer between the copper and the dielectric material in which the copper lines are embedded. Although silicon nitride is a dielectric material that effectively prevents the diffusion of copper atoms, selecting silicon nitride as an interlayer dielectric material is less then desirable, since silicon nitride exhibits a moderately high permittivity, thereby increasing the parasitic capacitance of neighboring copper lines. Hence, a thin conductive barrier layer that also imparts the required mechanical stability to the copper is formed so as to separate the copper from the surrounding dielectric material and only a thin silicon nitride or silicon carbide or silicon carbonitride layer in the form of a capping layer is frequently used in copper-based metallization layers. Currently, tantalum, titanium, tungsten and their compounds, with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques. In addition, copper may not be efficiently patterned by anisotropic dry etch processes, thereby requiring a process strategy that is commonly referred to as the damascene or inlaid technique. In the damascene process, first a dielectric layer is formed that is then patterned to include trenches and vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, which thus requires the reliable filling of vias with an aspect ratio of 5 and more with a diameter of approximately 0.1 μm or less in combination with trenches having a width ranging from approximately 0.1 μm or less to several μm. Although electrochemical deposition processes for copper are well established in the field of electronic circuit board fabrication, a substantially void-free filling of high aspect ratio vias is an extremely complex and challenging task, wherein the characteristics of the finally obtained copper metal line significantly depend on process parameters, materials and geometry of the structure of interest. Since the geometry of interconnect structures is determined by the design requirements and may, therefore, not be significantly altered for a given microstructure, it is of great importance to estimate and control the impact of manufacturing processes involved in the fabrication of metallization layers and of materials, such as conductive and nonconductive barrier layers, of the copper microstructure and their mutual interaction on the characteristics of the interconnect structure so as to insure both high yield and the required product reliability.

Accordingly, a great deal of effort has been made in investigating the degradation of copper lines, especially in view of electro and stress migration and undue conductivity reduction in highly scaled devices, in order to find new materials and process strategies for forming copper-based metal lines, as increasingly tighter constraints are imposed with respect to the electro and stress migration and conductivity characteristics of copper lines with the continuous shrinkage of feature sizes in advanced devices. Although the exact mechanism of electro and stress migration in copper lines is still not quite fully understood, it turns out that voids positioned in and on sidewalls and interfaces may agglomerate to form large bulk voids which finally result in a resistance increase and eventually a total failure.

Empirical research results indicate that the degree of electromigration and stress-induced migration frequently depends on the material composition of the metal, the crystalline structure of the metal, the condition of any interfaces connecting to neighboring materials, such as conductive and dielectric barrier layers and the like. For example, the grain boundaries in the interconnect structure represent preferred diffusion paths for current-induced material diffusion as the reduction of the width of metal lines tends to generate smaller grains, therefore, an over-proportional increase of electromigration may occur upon further device scaling.

With reference to FIGS. 1a-1c, a typical conventional electromigration behavior may be described in more detail, wherein reduced lifetime and reduced reliability of complex metallization systems may be encountered upon reducing the overall dimensions of the interconnect structures.

FIG. 1a schematically illustrates a cross-sectional view of a semiconductor device 100 which comprises a metallization system of which, for convenience, two metallization layers 120 and 110 are illustrated. In sophisticated applications, the metallization layer 120 typically comprises a dielectric material, such as a low-k dielectric material, which is to be understood as dielectric material having a dielectric constant of 3.0 and less. An interconnect structure in the form of a metal line 122 is embedded in the dielectric material 121 and comprises a highly conductive material, such as copper, as a core or fill material 122A, wherein also conductive barrier materials 122B have to be provided in combination with copper-based metallization systems in order to provide superior copper confinement, as discussed above. Furthermore, a cap layer 123, such as a nitrogen-containing silicon carbide material and the like, may be provided above the dielectric material 121 and the interconnect structure 122. Similarly, the metallization layer 110 comprises a dielectric material 111, typically in the form of a low-k dielectric material, in which is embedded an interconnect structure 112, for instance comprising a metal line 112L, and a via 112V, which in turn connects to the metal line 122 of the lower-lying metallization layer 120. The interconnect structure 112 comprises a core or fill metal 112A, for instance in the form of copper, in combination with a conductive barrier material 112B. For example, frequently, tantalum, tantalum nitride and the like are preferably used as conductive barrier materials to provide superior adhesion and confinement of the core metal 112A.

The semiconductor device 100 as shown in FIG. 1a may be formed on the basis of sophisticated process techniques. That is, after forming any circuit elements in a device level (not shown) by applying sophisticated manufacturing techniques in order to form semiconductor-based circuit elements, such as transistors with critical dimensions according to the design rules, the metallization system may be formed by sequentially forming the metallization layers 120, 110. To this end, in copper-based metallization regimes, an inlaid technique is applied in which the dielectric material 121 is deposited and possibly treated in order to obtain the desired material characteristics. It should be appreciated that the dielectric material 121 may be provided in the form of two or more different material compositions, depending on the overall complexity of the metallization system under consideration. Thereafter, various process strategies may be applied, which eventually result in the formation of corresponding trenches and openings, which are subsequently filled with the conductive materials 122B, 122A. It should be appreciated that, depending on the packing density in the device level and thus depending on the minimum critical dimensions to be implemented therein, also the lateral dimensions of the corresponding trenches and openings for the inter-connect structures 122, 112 have to be adapted, thereby requiring lateral dimensions of 100 nm and significantly less in sophisticated applications. Consequently, the associated manufacturing processes for patterning the dielectric material 121 and for filling in the conductive materials 122B, 122A may represent very complex process techniques, which may have a significant influence on the finally obtained performance of the interconnect structure 122.

For example, appropriate barrier materials may be deposited by physical vapor deposition (PVD), such as sputter deposition, chemical vapor deposition (CVD), electrochemical deposition techniques and the like. Thereafter, if required, a seed layer, such as a copper layer, is formed on the barrier layer 122B so as to provide superior conditions for the subsequent deposition of the actual core metal 122A, which is typically accomplished on the basis of electrochemical deposition processes. Thereafter, usually appropriate treatments, such as heat treatments, are performed in order to provide superior crystallinity of the core metal 122A, as will be described below with respect to the metallization layer 110. Prior to or after any such treatments, any excess material may be removed, for instance by chemical mechanical polishing (CMP), followed by the deposition of the cap layer 123, which may thus be directly formed on the core metal 122A, thereby forming an interface whose quality may strongly influence the finally achieved electromigration behavior. Thereafter, the metallization layer 110 may be formed on the basis of similar process techniques as described above with reference to the metallization layer 120. Consequently, the interconnect structure 112 is obtained with a core metal 112A and the barrier material 112B, wherein the crystalline structure of the core material 112A may significantly depend on the process history and in particular on the overall lateral dimensions of the interconnect structure 112. Typically, it is attempted to provide large metal grains 112G, since an increased number of grain boundaries may generally result in increased scattering of charge carriers, thereby increasing the overall resistivity of the interconnect structures. Furthermore, as discussed above, grain boundaries have also been identified as defective diffusion paths during the current-induced material diffusion during operation of the device 100.

FIG. 1b schematically illustrates the interconnect structure 112 of the semiconductor device 100 during operation. That is, typically a high current density of several Ka per square meter may occur and may thus induce material migration along the interconnect structure 112. For example, in particular an interface 113S formed by the cap layer 113 and the core metal 112A may represent a “weak” interface in which a moderately low activation energy is sufficient to induce material migration. In this manner, increasingly voids may form, preferably at the interface 113S, and may increasingly “agglomerate” at sensitive areas in the interconnect structure, for instance at a transition area between the via 112V and the metal line 112L. For example, a void 114 may form and its size may increase since a further void 114A may “move” along the weak interface 113S so that finally the overall resistance of the interconnect structure 112 may increase, thereby eventually resulting in a total failure of the interconnect structure 112. Hence, significant efforts are being made in determining the corresponding lifetime and process conditions in order to provide a reliable estimation of a time to failure of critical interconnect structures in order to be able to predict the expected lifetime of complex semiconductor devices.

FIG. 1 c schematically illustrates the situation with the semiconductor device 100 when the lateral dimensions of the interconnect structure 112 have to be reduced, for instance in order to comply with reduced ground rules in the device level. For example, in sophisticated applications, semiconductor-based circuit elements having critical dimensions of 40 nm and less may require a corresponding adaptation of the lateral dimensions of the interconnect structure 112 in the metallization system. It has been recognized that the size of the grains 112G may tend to become smaller, in particular at the bottom of the metal line 112 so that, in addition to the interface 113S, also “efficient” diffusion paths may be created at the bottom of the interconnect structure 112 so that any corresponding voids 114C may also finally accumulate in sensitive device areas, thereby forming the void 114 of increased dimensions. Due to the additional fusion paths provided by the grains 112G of reduced size, generally electrical performance may be reduced and at the same time the time to failure due to severe electromigration effects may also be reduced. Since the problem of a reduced grain size in the deeper portion of metal lines may be further pronounced upon further scaling the overall device dimensions, significant performance degradation in view of electrical performance and reduced reliability may result.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure provides techniques and semiconductor devices in which enhanced performance with respect to electromigration may be accomplished in sophisticated metallization systems by incorporating an interface of superior electromigration resistance, i.e., an interface having a higher activation energy in order to efficiently block or at least reduce current-induced material migration through the interface layer. In some illustrative aspects disclosed herein, a corresponding interface of superior electromigration behavior or void blocking characteristics may be incorporated into a lower portion of at least a significant length of corresponding interconnect structures, thereby appropriately isolating portions of a core metal or fill metal in which typically grains of reduced size may be generated. In this manner, the additional line degradation mechanism caused by reduced grain sizes, lower portions of interconnect structures and metal lines may be efficiently blocked or at least reduced in its effect. Consequently, complex metallization systems may be formed so as to comply with critical dimensions of approximately 40 nm and less in the device level without unduly restricting the resulting lifetime by pronounced electromigration effects, as may be the case in conventional process strategies.

One illustrative method disclosed herein comprises forming a trench in a dielectric layer of a metallization layer of a semiconductor device. Moreover, a first portion of a fill metal is formed in the trench and an interface layer is formed on an exposed surface of the first portion. The interface layer has a different material composition compared to the exposed surface of the first portion. Additionally, the method comprises forming a second portion of the fill metal above the interface layer.

A further illustrative method disclosed herein relates to forming an interconnect structure of a metallization system of a semiconductor device. The method comprises performing a first deposition process so as to form a first fill metal in an opening that is formed in a dielectric material of the metallization system. The method further comprises forming an interface layer of superior electromigration resistance on an exposed surface of the first fill metal. Additionally, the method comprises performing a second deposition process so as to form a second fill metal in the opening and above the interface layer.

One illustrative semiconductor device disclosed herein comprises a metallization layer formed above a substrate and comprising a dielectric material. Furthermore, a metal line is embedded in the dielectric material and comprises a first fill metal portion and a second fill metal portion, which are separated by an interface layer. The interface layer has a material composition that differs from a material composition of the first and second fill metal portions.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a metallization system of a complex semiconductor device formed in accordance with conventional process strategies;

FIGS. 1b-1c schematically illustrate cross-sectional views of a conventional interconnect structure with different lateral dimensions during the operation of the semiconductor device, thereby resulting in reduced electromigration reliability;

FIGS. 2a-2d schematically illustrate cross-sectional views of a semiconductor device during various manufacturing stages in forming a complex metallization layer including interconnect structures of superior electromigration performance by incorporating an interface layer, according to illustrative embodiments; and

FIG. 2e schematically illustrates an interconnect structure comprising an interface layer during operation, wherein the interface layer may efficiently block void agglomeration, which may conventionally be caused by a reduced grain size in lower portions of highly scaled interconnect structures.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally contemplates manufacturing techniques and semiconductor devices in which the effect of reduced grain size, in particular in lower portions of highly scaled interconnect structures, may be significantly reduced. To this end, an appropriate interface layer may be incorporated into the fill material of the interconnect structure in order to provide a highly stable interface to a plurality of grains of reduced size, which may result in a reduced material migration and thus void agglomeration compared to conventional interconnect structures having similar lateral dimensions. The interface layer may be formed on the basis of any material composition that may form a strong interface with the core metal or fill metal so that material migration through the interface layer may be substantially blocked. To this end, any appropriate conductive materials, such as conductive barrier materials in the form of tantalum, tantalum nitride, titanium, titanium nitride, tungsten and the like, may be used. Moreover, any other established ternary alloys, for instance comprising cobalt, tungsten, boron and the like, may be used in order to incorporate the interface layer so as to have superior electromigration performance. In other illustrative embodiments disclosed herein, the interface layer may be formed on the basis of a surface treatment, for instance by using a silane-containing process atmosphere in order to initiate the formation of a copper silicide, which is also known to have superior interface characteristics in terms of electromigration resistance. In other cases, the interface layer may be formed by a deposition process in combination with an appropriate treatment, for instance by depositing at least one species, such as silicon, which may be subsequently converted into a copper silicide by applying appropriate process conditions.

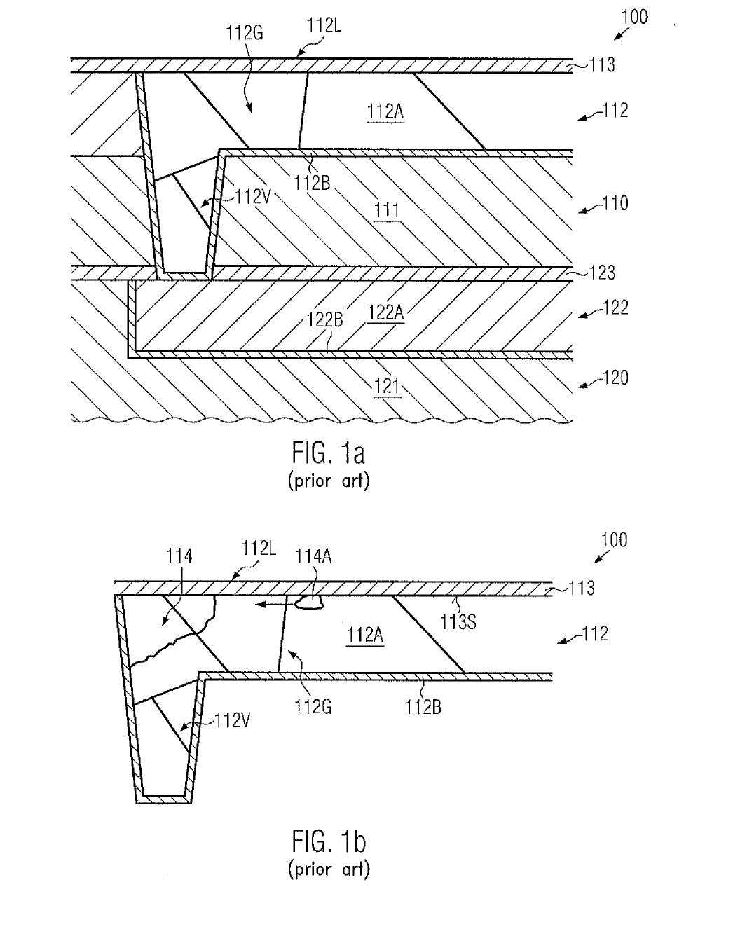

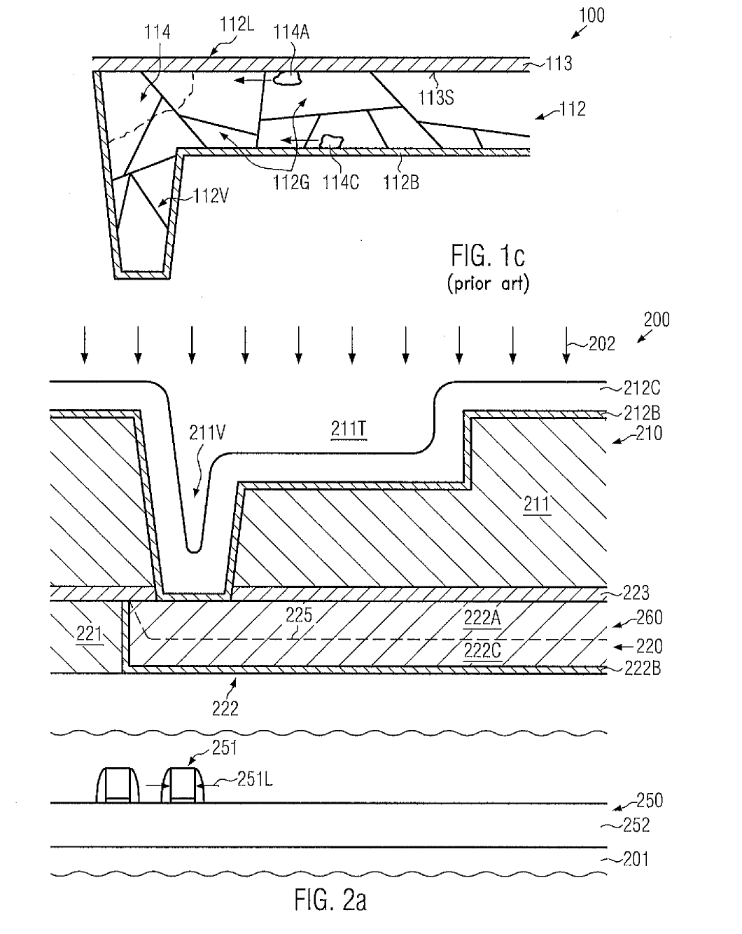

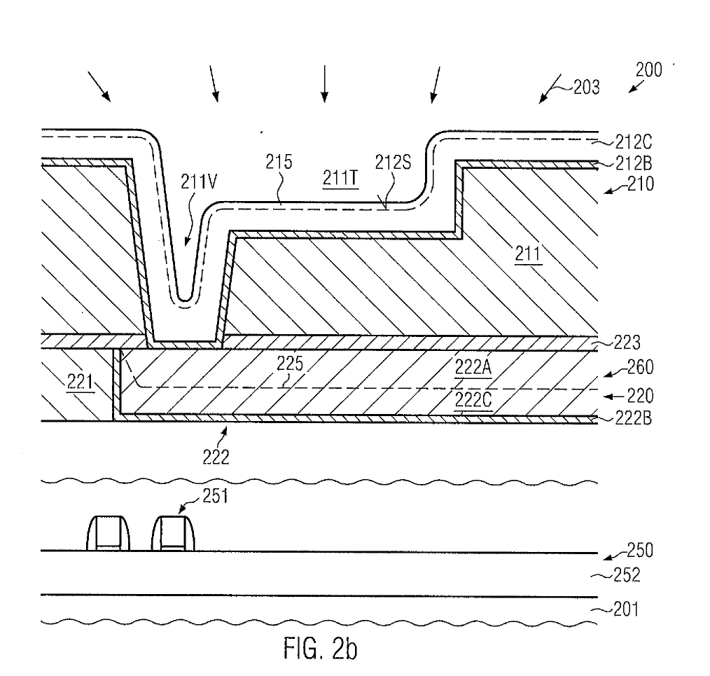

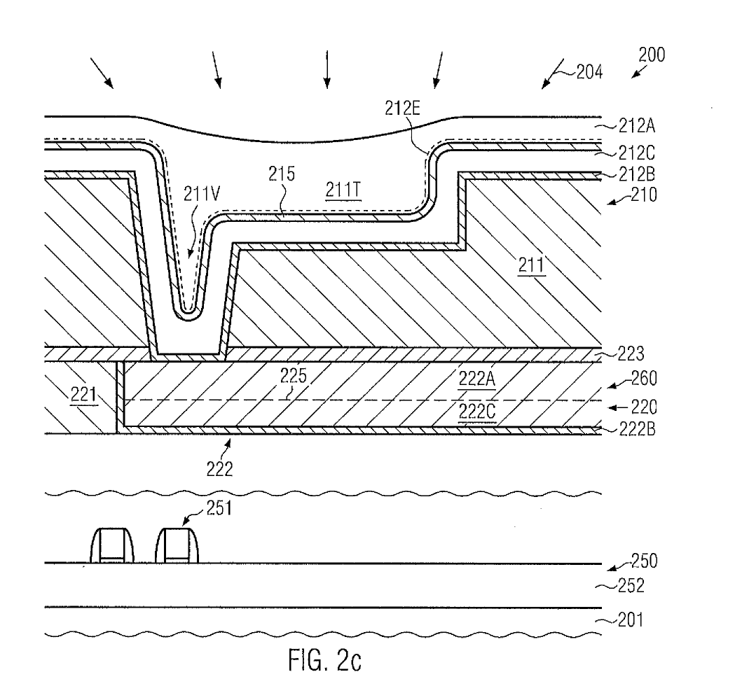

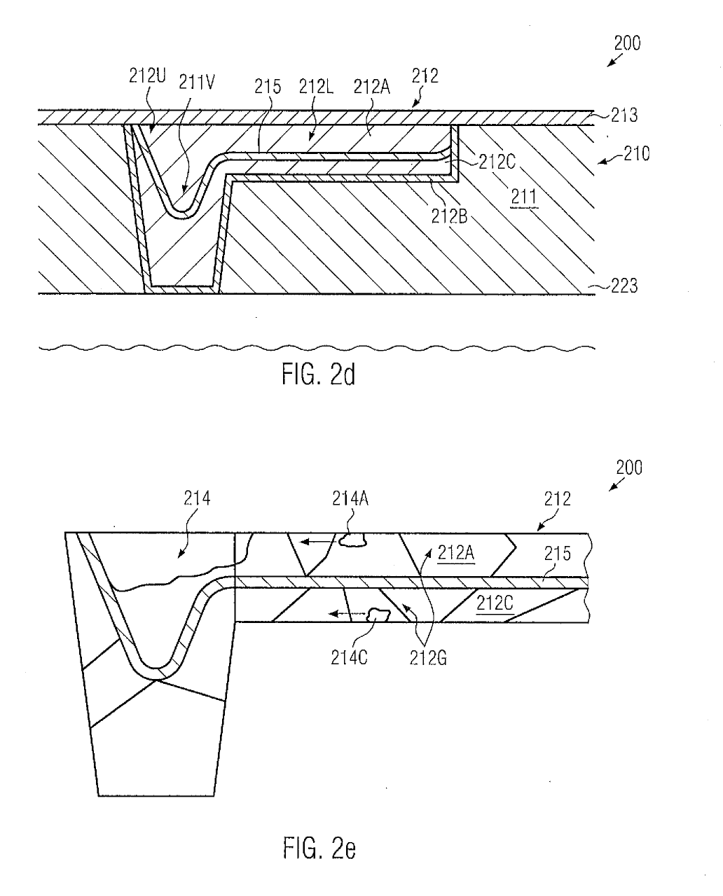

With reference to FIGS. 2a-2e, further illustrative embodiments will now be described in more detail, wherein reference may also be made to FIGS. 1a-1c, if required.

FIG. 2a schematically illustrates a cross-sectional view of a semiconductor device 200 in an advanced manufacturing stage. As shown, the semiconductor device 200 may comprise a substrate 201, such as a silicon substrate or any other appropriate material, and a device level 250. The device level 250 may comprise any appropriate semiconductor layer 252, such as a silicon layer, a silicon/germanium layer and the like, as may be required for forming sophisticated circuit elements. In some illustrative embodiments, the circuit elements 251 may comprise transistors formed on the basis of critical dimensions of 40 nm and less, which may thus require appropriately adapted lateral dimensions of interconnect structures in a metallization system 260 formed above the device level 250. It should be appreciated that the principles disclosed herein may be highly advantageously applied in the context of semiconductor devices including circuit elements based on critical dimensions in the above-defined range, wherein, however, the principles disclosed herein may also be applied to semiconductor devices including less critical circuit elements in order to further enhance reliability and electrical performance of any such devices. For example, the circuit elements 251 may comprise field effect transistors having a gate length 251L of 40 nm and less.

As discussed before, the metallization system 260 may typically comprise a plurality of metallization layers, wherein, for convenience, metallization layers 220, 210 may be illustrated in FIG. 2a. The metallization layer 220 may comprise any appropriate dielectric material or material system 221, in which interconnect structures, for instance in the form of metal lines 222 and vias or any other vertical contacts (not shown) may be provided. For example, as also previously discussed with reference to the device 100, the dielectric material 221 may comprise a low-k dielectric material. The metal line 222 may have core metal or fill metal, for instance provided in the form of a first portion 222A and a second portion 222C, which may be separated, at least within a major part of the metal line 222, by an interface layer 225, which may provide superior electromigration behavior of the metal line 222. The interface layer 225 may be provided in the form of a material forming a “strong” interface with any of the fill metal portions 222A, 222C so that higher activation energy may be required for initiating current-induced material diffusion, as is also discussed above. For example, the interface layer 225 may comprise well-established barrier materials, such as tantalum, tantalum nitride, titanium, titanium nitride, tungsten compounds, ternary alloys such as cobalt phosphorous tungsten, cobalt boron tungsten and the like, copper silicide and the like. Furthermore, a dielectric cap layer 223 may be formed above the dielectric material 221 and on the metal line 222, thereby also confining the fill metal portions 222A, 222C.

Furthermore, a barrier material system 222B may be provided, in particular in combination with a copper fill metal, in order to enhance adhesion to the dielectric material 221 and copper diffusion to the surrounding dielectric materials. For example, the conductive barrier material system 222B may comprise tantalum, tantalum nitride and the like. It is well known that any such conductive barrier materials may form a strong interface with copper so that any current-induced material diffusion may not occur within the conductive material 222B. and also material migration through the barrier material system 222B may be efficiently blocked unless undue overall electromigration is avoided in the metal line 222.

The metallization layer 210 is illustrated in an intermediate manufacturing stage, i.e., a dielectric material or material system 211, which may comprise a low-k dielectric material, may be formed above the layer 220 and may comprise a trench 211T, possibly in combination with a via opening 211V, when a dual damascene process strategy is considered. In other cases, vias and trenches may be filled with any appropriate fill metal in separate deposition steps. Moreover, in this manufacturing stage, a conductive barrier material or material system 212B may be formed on any exposed surface areas of the dielectric material 211 and thus also within the via opening 211V and the trench 211T. Furthermore, a first portion of a fill metal 212C may be formed in the via opening 211V and the trench 211T.

The semiconductor device 200 as shown in FIG. 2a may be formed on the basis of the following process strategies. The semiconductor-based circuit element 251 in the device level 250 may be formed on the basis of any appropriate process strategy, which may include sophisticated lithography techniques, etch processes, planarization techniques, implantation processes and the like, in order to form the circuit elements 251 in accordance with the associated design rules. Thereafter, the circuit elements 251 may be appropriately passivated by forming a contact level, which may also provide vertical contacts so as to connect to the metallization system 260. Since the circuit elements 251 may be provided with reduced lateral dimensions and thus also with a reduced lateral pitch, corresponding contacts and interconnect structures of the metallization system 260 may have to be adapted so as to comply with the required packing density in the device level 250, thereby requiring lateral dimensions of 100 nm and significantly less. Thereafter, the metallization layers 220, 210 may be formed, wherein the metallization layer 220 may be formed on the basis of similar process techniques as will be described with reference to the metallization layer 210. To this end, after forming the cap layer 223, which may be provided in some illustrative embodiments in the form of a dielectric material, thereby avoiding the deposition of complex conductive cap materials, which, however, may not efficiently improve the electromigration behavior caused by grain size issues, as discussed above with reference to FIG. 1c, the dielectric material or material system 211 may be formed, for instance, by depositing one or more materials of appropriate dielectric constant. Thereafter, complex patterning strategies may be applied, for instance using sophisticated hard mask approaches in combination with appropriate lithography techniques, in order to form the trench 211T and the via opening 211V. It should be appreciated that any appropriate patterning strategy may be applied, wherein, in the embodiment shown, the via opening 211V and 211T may be provided so as to be filled in a common deposition process sequence, while in other cases the via opening 211V may be formed in a first portion of the dielectric material 211 and may be filled in a separate deposition sequence.

In the embodiment shown, the barrier material or material system 212B may be formed by using any appropriate deposition technique, such as sputter deposition, CVD and the like, in order to form the material 212B in a reliable manner at any exposed surface area within the trench 211T and the via opening 211V. Thereafter, depending on the overall process strategy, in some illustrative embodiments, a seed layer (not shown) may be formed on the barrier material system 212B, for instance comprised of copper, which may be applied on the basis of physical vapor deposition and the like. Thereafter, a deposition process 202 may be applied in order to form the first fill metal portion 212C, for instance comprised of copper or any other highly conductive fill metal. To this end, frequently, electrochemical deposition techniques may be applied, such as electroless deposition, electroplating or any combination thereof, in which appropriate process parameters are applied so as to obtain a desired bottom-to-top fill behavior. The deposition process 202 may be controlled so as to provide a certain desired thickness of the first portion 212C, for instance within the trench 211T, in order to form thereon an appropriate barrier or blocking layer in view of superior electromigration behavior. To this end, the process time for given deposition parameters may be appropriately controlled in order to adjust the thickness of the first fill metal portion 212C.

FIG. 2b schematically illustrates the semiconductor device 200 in a further advanced manufacturing stage in which an intermediate process may be applied so as to form an interface layer 215 on exposed surface areas 212S of the first fill metal portion 212C. To this end, in some illustrative embodiments, the process 203 may be applied in the form of a deposition process, such as a CVD process, a PVD process, in order to form the interface layer 215 with a desired material composition. For example, well-established barrier materials, such as tantalum, tantalum nitride, titanium, titanium nitride or any combination thereof, may be deposited by using well-established deposition recipes. The interface layer 215 may be provided with a thickness of approximately 2-10 nm, wherein the resulting surface topography is less critical compared to the deposition of the conductive barrier material 212B, since, in particular, the via opening 211V may already be filled up to a certain height level by means of the preceding deposition process for forming the first fill metal portion 212C. In other illustrative embodiments, the process 203 may be performed on the basis of an electrochemical deposition process, such as an electroless process, in order to form the interface layer 215 with any appropriate material. For example, a plurality of barrier materials may be deposited on the basis of electroless deposition recipes, wherein, in some illustrative embodiments, well-established alloys, such as cobalt and tungsten-containing alloys, may be formed which are known to provide superior surface and interface characteristics in combination with a highly conductive fill metal, such as copper. In this case, a well-controllable uniform layer thickness may be obtained on the surface 212S so that reduced thickness may nevertheless provide a desired reliable coverage of the exposed surface 212S. For example, in this case, a thickness of 1-5 nm may be applied, wherein, if required, also an increased thickness may be applied in a highly controllable manner.

In still other illustrative embodiments, the process 203 may comprise a surface treatment so as to modify the surface 212S or form a corresponding surface layer, which may provide the desired blocking effect with respect to current-induced material fusion. In some illustrative embodiments, the process 203 may comprise the exposure to a reactive process atmosphere, for instance established on the basis of silane, which may thus interact with the copper atoms at the surface 212S in order to form a copper silicide, which is known to provide superior interface characteristics and which may also have a higher conductivity compared to a plurality of conventional barrier layer systems. In this manner, the intermediate interface layer 215 may provide a high blocking effect, for instance with respect to void migration, as discussed above, while at the same time the overall conductivity of the resulting interconnect structure may not be unduly affected by the presence of the interface layer 215. In other illustrative embodiments, the process 203 may be performed so as to incorporate an alloy-forming species, such as aluminum and the like, which may be accomplished by establishing an appropriate plasma ambient or by performing a low energy implantation process. The incorporation of an alloy-forming species, such as aluminum, may significantly enhance the electromigration behavior. Moreover, the thickness of the resulting interface layer 215 may be adjusted on the basis of a further treatment, such as a heat treatment, in order to initiate diffusion of the alloy-forming species. In this manner, the alloy-forming species may be distributed through at least a significant portion of the first fill metal portion 212C, if considered appropriate.

In still other illustrative embodiments, the process 203 may comprise a deposition process for depositing at least one species on the interface layer 215. For example, a silicon material may be deposited on the exposed surface 212S and may be subsequently converted into a copper silicide in order to form the interface layer 215.

FIG. 2c schematically illustrates the semiconductor device 200 in a further advanced manufacturing stage in which a further deposition process 204 may be applied so as to provide a second fill metal portion 212A in order to reliably fill the trench 211T and, if provided in this manufacturing stage, the via opening 211V. To this end, any well-established electrochemical deposition technique may be applied, wherein, however, appropriate process parameters may be adjusted, which may differ from the first deposition process for forming the first fill metal portion 212C, since a less critical surface topography may be encountered upon performing the deposition process 204. Moreover, in some illustrative embodiments, prior to actually forming the fill metal portion 212A, a seed layer 212E may be deposited, if required, for instance in the form of a copper material and the like. To this end, any well-established deposition techniques may be applied, such as sputter deposition. It should be appreciated, however, that, in some illustrative embodiments, the second fill metal portion 212A may be directly deposited on the interface layer 215 on the basis of electrochemical deposition recipes, when the interface layer 215 may provide sufficient surface conditions so as to initiate the deposition of the fill metal.

FIG. 2d schematically illustrates the semiconductor device 200 in a further advanced manufacturing stage. As shown, any excess material of the previously deposited conductive material may be removed, which may be accomplished on the basis of any appropriate removal process such as CMP, electro CMP, etching and the like, thereby forming an interconnect structure 212 as an electrically isolated feature within the metallization layer 210. Furthermore, a cap layer 213 may be formed above the interconnect feature 212 and may be provided, in some illustrative embodiments, in the form of a dielectric cap layer, which may also be formed on the dielectric material 211, thereby acting as a transition and/or etch stop layer for the subsequent patterning of a dielectric material of a next metallization layer. Consequently, the interconnect structure may comprise the intermediate interface layer 215, which may be positioned at a desired height level within, in particular, the metal line 212L, thereby in particular separating the lower portion 212C from a critical device area with respect to electromigration, such as an upper corner 212U of the via 211V.

FIG. 2e schematically illustrates the interconnect structure 212 of the device 200 during a typical stress situation in which a current- or stress-induced material diffusion may occur. As illustrated, corresponding grains 212G may be formed in the fill metal portion 212A and also in the lower fill metal portion 212C, which may have formed therein grain sizes of reduced size, as is also previously discussed with reference to FIG. 1 c. Consequently, by providing the interface layer 215 having the superior interface characteristics, a pronounced material diffusion through the layer 215 may be blocked, thereby also blocking or at least significantly reducing any diffusion paths, which may otherwise be provided by the grain boundaries in the lower areas of the metal line 212. Consequently, during any stress situation, voids may agglomerate at the critical device area, as indicated by the void 214, which may be “fed” by a moderate migration or movement of voids 214A, for instance “migrating” along the interface formed between the fill metal portion 212A and any cap material, such as the cap layer 213 of FIG. 2d. Consequently, although the interconnect structure 212 may have reduced lateral dimensions, thereby increasingly creating grains of reduced size at a lower portion, the effect of these grains of reduced size may be significantly reduced due to the presence of the interface layer 215. Consequently, by incorporating the interface layer 215, the interconnect structure 212 may be scaled in accordance with the device rules, however, without unduly reducing overall electromigration performance.

It should be appreciated that the interface layer 215 may be incorporated in the inter-connect features of any critical metallization layer, for instance in the metallization layer 220 as shown in FIG. 2a in the form of the interface layer 225, wherein, however, different materials and/or process strategies may be applied, if considered appropriate.

As a result, the present disclosure provides semiconductor devices and manufacturing techniques in which a significant improvement in electromigration lifetime may be achieved for a given design of a metallization system, since upon further reduction of lateral dimensions of the interconnect structures, an over-proportional electromigration effect may be avoided by incorporating an intermediate interface layer, which may efficiently block undue void or material migration. Consequently, much faster design cycles may be achieved in developing new integrated circuits since critical signal paths may not require a pronounced redesign, as may be the case in conventional strategies. Moreover, well-established process techniques and materials, such as dielectric cap layers for confining the interconnect structures, may be applied, thereby using overall production costs compared to conventional strategies in which it is attempted to prove electromigration behavior on the basis of complex cap layer systems.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench in a dielectric layer of a metallization layer of a semiconductor device;
forming a first portion of a fill metal in said trench;
forming an interface layer on an exposed surface of said first portion, said interface layer differing in its material composition relative to said exposed surface of said first portion; and
forming a second portion of said fill metal above said interface layer.

2. The method of claim 1, wherein said semiconductor device comprises semiconductor-based circuit elements having critical dimensions of 40 nm or less.

3. The method of claim 1, further comprising forming a conductive barrier layer on exposed surface areas of said trench prior to forming said first portion of said fill metal.

4. The method of claim 1, wherein forming said interface layer comprises depositing at least one species of said interface layer on said exposed surface.

5. The method of claim 4, wherein depositing said at least one species of said interface layer comprises performing one of physical vapor deposition and chemical vapor deposition.

6. The method of claim 4, wherein depositing at least one species of said interface layer comprises performing an electrochemical deposition process.

7. The method of claim 1, wherein forming said interface layer comprises performing a surface treatment on said exposed surface.

8. The method of claim 7, wherein forming said interface layer further comprises depositing at least one species of said interface layer so as to be modified on the basis of said surface treatment.

9. The method of claim 1, further comprising forming a seed layer on said interface layer prior to forming said second portion of said fill metal.

10. The method of claim 1, wherein said fill metal comprises copper.

11. The method of claim 10, wherein said interface layer comprises at least one of tantalum, titanium, tungsten, cobalt, nitrogen and silicon.

12. The method of claim 1, further comprising a via opening and forming said first and second portions of said fill metal commonly in said via opening and said trench.

13. A method of forming an interconnect structure of a metallization system of a semiconductor device, the method comprising:
performing a first deposition process so as to form a first fill metal in an opening formed in a dielectric material of said metallization system;
forming an interface layer of superior electromigration resistance on an exposed surface of said first fill metal; and
performing a second deposition process so as to form a second fill metal in said opening and above said interface layer.

14. The method of claim 13, wherein forming said interface layer comprises performing an intermediate deposition process so as to deposit at least one species of said interface layer.

15. The method of claim 14, wherein performing said intermediate deposition process comprises depositing said interface layer.

16. The method of claim 13, wherein forming said interface layer comprises performing a surface treatment.

17. The method of claim 16, wherein said surface treatment is performed in the presence of silane.

18. A semiconductor device, comprising:
a metallization layer formed above a substrate and comprising a dielectric material; and
a metal line embedded in said dielectric material and comprising a first fill metal portion and a second fill metal portion, said first and second fill metal portions being separated by an interface layer, said interface layer having a material composition that differs from a material composition of said first and second fill metal portions.

19. The semiconductor device of claim 18, further comprising transistor structures having at least one critical dimension that is 40 nm or less.

20. The semiconductor device of claim 18, wherein said interface layer comprises at least one of tantalum, titanium, tungsten, cobalt, nitrogen and silicon.
